(19) United States
(12) Patent Application Publication
(10) Pub. No.: US 2014/0168865 A1
(43) Pub. Date: Jun. 19, 2014

(54) DEVICE FOR SUPPORTING TOUCH PANEL

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventor: XIONG HUANG, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/730,713

(22) Filed: Dec. 28, 2012

(30) Foreign Application Priority Data
Dec. 13, 2012 (CN) 201210537030.7

(51) Int. Cl. H05K 7/18

(52) U.S. Cl. CPC H05K 7/18
USPC 361/679.01

(57) ABSTRACT

A device for supporting a touch panel is provided. The device includes a support block, an obliquely oriented first plate, a black plate and a fixing mechanism. The first plate has a first end raised and mounted on the support block, and an opposite second end being placed on the level surface thereby forming a main plane of the first plate is inclined at an angle of approximately 80 degrees relative to the level surface. A touch panel is placed on the first plate. The black plate is placed on the first plate below the touch panel. The fixing mechanism is arranged on the first plate, and positions the black plate and the touch panel on the first plate.

### BACKGROUND

1. Technical Field

The present disclosure relates to devices and, particularly, to a device for supporting a touch panel.

2. Description of Related Art

In related art, a touch panel is usually picked up by a user for observing whether there is white spot, smudginess, scratch and/or breach in the touch panel. However, the hands of a user themselves can stain the clean surface of a touch panel. The touch panel being transparent means that it is difficult to observe whether there is white spot in the touch panel.

Therefore, what is need is a device for supporting a touch panel to overcome the described limitations.

### BRIEF DESCRIPTION OF THE DRAWINGS

FIG. 1 is an isometric view of a device in accordance with a first exemplary embodiment.

FIG. 2 is an isometric view of the device in accordance with a second exemplary embodiment.

FIG. 3 is an exploded view of the device of FIG. 2.

FIG. 4 is a schematic diagram of the device of FIG. 2, when the device is being used to support the touch panel.

FIG. 5 is a sectional view of the device of FIG. 2.

### DETAILED DESCRIPTION

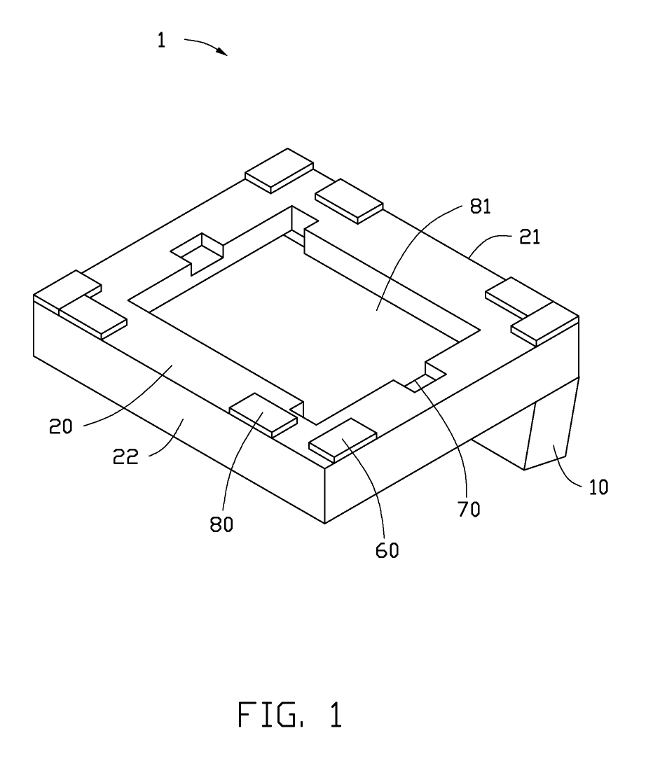

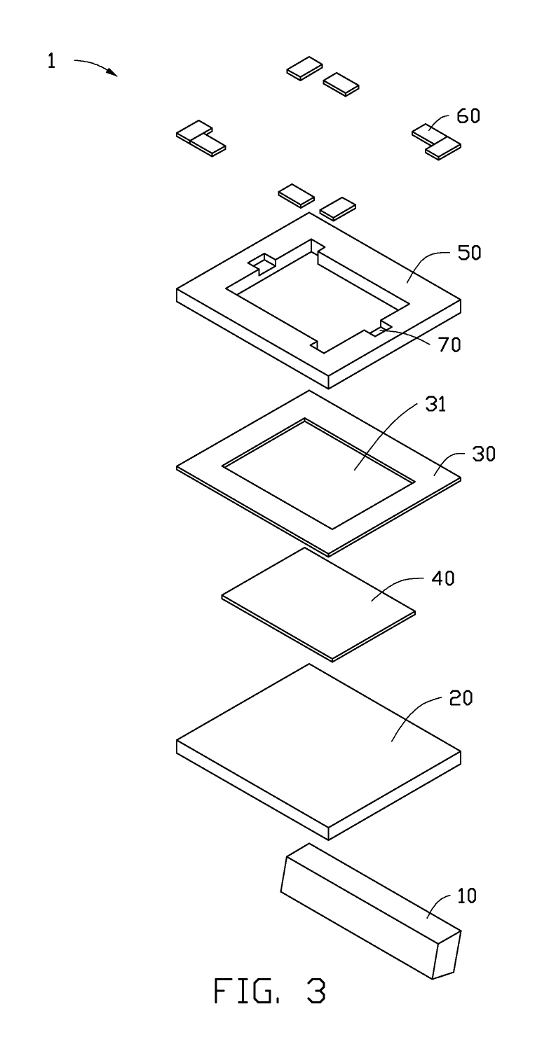

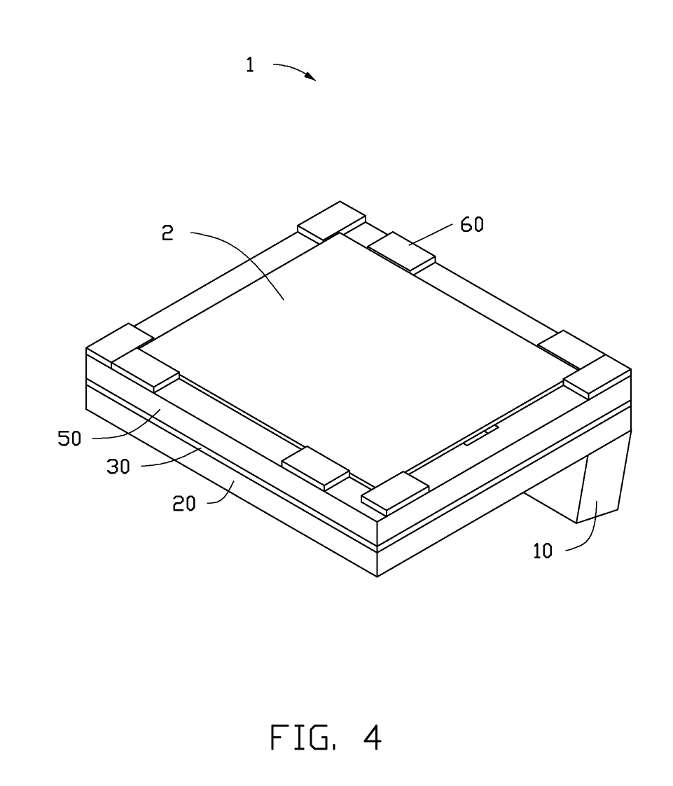

Referring to FIG. 1, a device 1 for supporting a touch panel 2 (see, FIG. 4) is provided. In a first embodiment, the device 1 includes a support block 10, a obliquely oriented first plate 20, a black plate 40 (see FIG. 3) placed on the obliquely oriented first plate 20, and a fixing mechanism 80 arranged on the first plate 20. The first plate 20 has a first end 21 and a opposite second end 22. The first end 21 is raised and mounted on the support block 10, the second end 22 is for being placed on the level surface thereby forming a main plane of the first plate which is inclined at an angle of approximately 80 degrees relative to the level surface. The touch panel 2 is placed on the first plate 20. The fixing mechanism 80 positions the black plate 40 and the touch panel 2 on the first plate 20. The touch panel 2 gives a contrast against the black plate 40 to help the user to clearly observe whether there is any white spot or similar defect in the touch panel 2. Simultaneously, due to the angle between the support block 10 and the first plate 20, it is easy for the user to observe whether there is smudginess, scratch and/or breach in the touch panel 2 from a side view. The first plate 20 defines a number of holes 70 on a top surface thereof. The number of holes 70 are configured for receiving a number of components (not labeled) of the touch panel 1 thereby a shelter or recess which prevents damage to the components.

In a first embodiment, the fixing mechanism 80 includes a number of resisting blocks 60 arranged along a periphery of the first plate 20. The number of resisting blocks 60 cooperatively retains the black plate 40 and the touch panel 2 on the first plate 20. In a second embodiment, the fixing mechanism 80 includes a number of resisting blocks 60 arranged along a periphery of the first plate 20, and defines a recess 81 in the first plate 20. The number of the resisting blocks 60 cooperatively retains the touch panel 2 on the first plate 20. The recess 81 receives the black plate 40 therein.

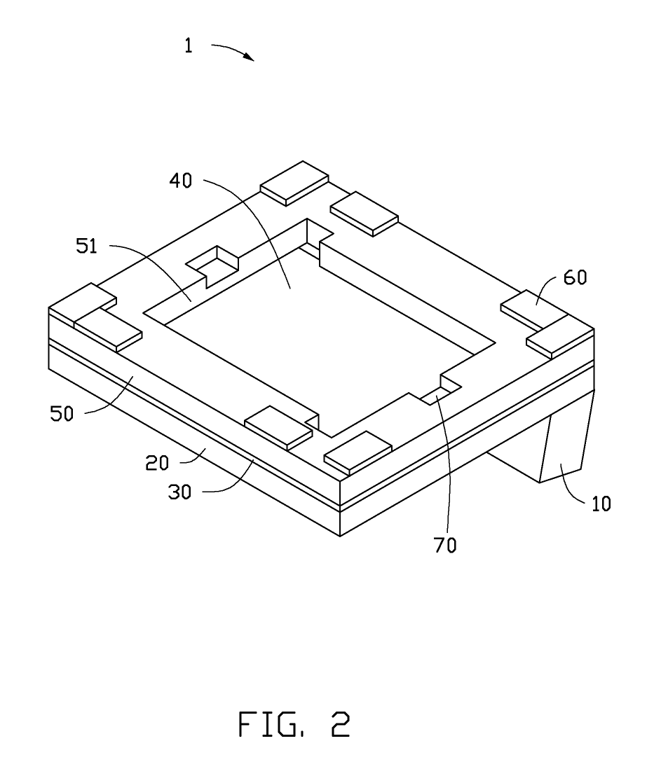

As referred to FIGS. 2-3, in a second embodiment, the device 1 further includes a second plate 50 placed on the black plate 40. The second plate 50 defines an opening 51 to expose the black plate 40. The fixing mechanism 80 is arranged on the second plate 50. The touch panel 2 is placed on the second plate 50. The fixing mechanism 80 positions the touch panel 2 on the second plate 50. In the second embodiment, the fixing mechanism 80 includes a number of resisting blocks 60 arranged along a periphery of the second plate 50. The number of resisting blocks 60 retains the black plate 40 on the second plate 50. The second plate 50 defines a number of holes 70 on a top surface thereof. The number of holes 70 are configured for receiving a number of components (not labeled) of the touch panel 1 as protection shields or recesses preventing damage to the components.

In one embodiment, the black plate 40 is a liquid crystal display panel. The device 1 further includes a third plate 30 placed on the first plate 20. The thickness of the third plate 30 is equal to the thickness of the black plate 40. The third plate 30 defines an through hole 31 for receiving the black plate 40 therein.

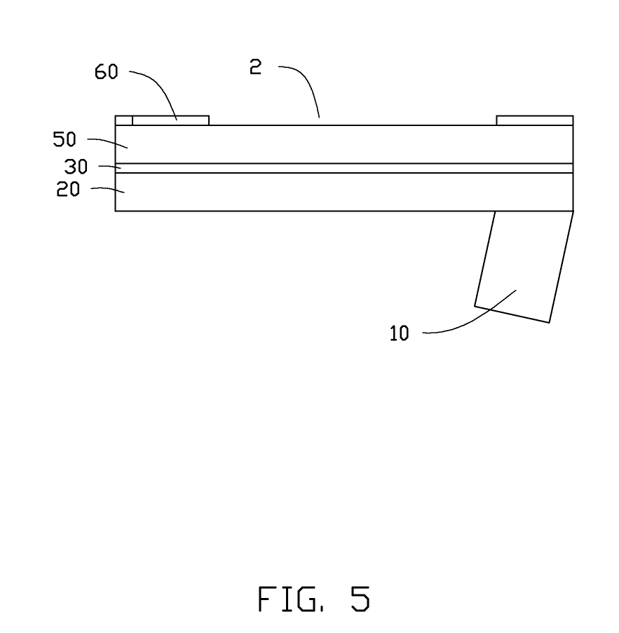

As referred to in FIGS. 4-5, when the user is examining the touch panel 2, the touch panel 2 is placed on the second plate 50. The user observes whether there is any white spot, smudginess, scratch and/or breach in the touch panel 2 from a side view. After the touch panel 2 has been completely inspected, the touch panel 2 is moved by a vacuum tube instead of by hands of the user; thereby avoiding finger marks on the touch panel 2.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. A device for supporting a touch panel, the device comprising:
a support block;
an obliquely oriented first plate having a first end raised and mounted on the support block, and an opposite second end for being placed on the level surface thereby forming a main plane of the first plate which is inclined at an angle of approximately 80 degrees relative to the level surface, the first plate configured for placement of a touch panel thereon;
a black plate configured to be placed on the first plate below the touch panel; and
a fixing mechanism arranged on the first plate, and configured for positioning the black plate and the touch panel on the first plate.

2. The device as described in claim 1, wherein the fixing mechanism comprises a plurality of resisting blocks arranged along a periphery of the first plate, the plurality of resisting blocks are configured for cooperatively positioning the black plate and the touch panel on the first plate.

3. The device as described in claim 1, wherein the fixing mechanism comprises a plurality of resisting blocks and a recess defined in the first plate, the plurality of resisting blocks are configured for cooperatively retaining the touch panel on the first plate, the recess is configured for receiving the black plate therein.

4. The device as described in claim 1, wherein the first plate defines a plurality of holes configured for receiving a plurality of components of the touch panel.

5. The device as described in claim 1, wherein the black plate is a liquid crystal display panel.

6. The device as described in claim 1, further comprising a second plate placed on the black plate, wherein the second plate defines an opening to expose the black plate, the fixing mechanism is arranged on the second plate, the second plate is configured to support the touch panel thereon.

7. The device as described in claim 6, wherein the second plate defines a plurality of holes configured for receiving a plurality of components of the touch panel.

8. The device as described in claim 6, further comprising a third plate placed on the obliquely oriented first plate, wherein the thickness of the third plate is equal to the thickness of the black plate, the third plate defines a through hole for receiving the black plate therein.
